(19) United States
(12) Patent Application Publication
(10) Pub. No.: US 2023/0317662 A1
(43) Pub. Date: Oct. 5, 2023

(54) ELECTRONIC DEVICE WITH SENSOR FACE STRESS PROTECTION

(71) Applicant: Texas Instruments Incorporated, Dallas, TX (US)

(72) Inventors: Rafael Jose Guevara, Manila (PH); Laura May Antionette Dela Paz Clemente, Antipolo City (PH); Amin Sijelmassi, Dallas, TX (US); Kashyap Mohan, Irving, TX (US)

(21) Appl. No.: 17/710,348

(22) Filed: Mar. 31, 2022

(51) Int. Cl. H01L 23/00; H01L 23/31; H01L 21/56; H01L 23/29

(52) U.S. Cl. CPC H01L 24/16; H01L 24/11; H01L 24/13; H01L 24/17; H01L 23/3128; H01L 21/565; H01L 23/3135; H01L 23/295; H01L 2924/35; H01L 2924/182; H01L 2224/1601; H01L 2224/16237; H01L 2224/16227; H01L 2224/17135; H01L 2224/11849; H01L 2224/13147; H01L 2224/13553; H01L 2224/1357; H01L 2224/10126; H01L 2224/10145; H01L 2224/11013; H01L 2224/11019; H01L 2924/186

(57) ABSTRACT

An electronic device includes a substrate, a semiconductor die, and a molded package structure that encloses a portion of the semiconductor die and extends to a portion of the substrate. A sensor surface extends along a side of the semiconductor die, and conductive terminals extend outward from the side and have ends soldered to conductive features of the substrate. The side of the semiconductor die is spaced apart from the substrate and the conductive terminals forming a cage structure that laterally surrounds the sensor surface. The molded package structure has a cavity that extends between the sensor surface and the substrate, and the cavity extends in an interior of a cage structure formed by the conductive terminals.

### BACKGROUND

Precision circuits may include sensors to sense environmental conditions such as pressure, temperature, humidity, etc. near an integrated circuit or other packaged electronic device. Correct sensor circuit performance is helped by isolation of mechanical stress on a packaged semiconductor die. However, molding compound movement during mold filling and curing can lead to stresses on the die with filler particles in the mold compound exerting localized stresses when in contact with the die surface. The stresses can cause or exacerbate long term drift in precision sensor circuit performance specifications.

### SUMMARY

In one aspect, an electronic device includes a substrate, a semiconductor die, and a molded package structure that encloses a portion of the semiconductor die and extends to a portion of the substrate. A sensor surface extends along a side of the semiconductor die, and conductive terminals extend outward from the side and have ends soldered to conductive features of the substrate. The side of the semiconductor die is spaced apart from the substrate and the conductive terminals forming a cage structure that laterally surrounds the sensor surface. The molded package structure has a cavity that extends between the sensor surface and the substrate, and the cavity extends in an interior of a cage structure formed by the conductive terminals.

In another aspect, a method includes forming conductive terminals along a side of a semiconductor wafer in a cage structure that laterally surrounds a sensor surface of the side of the semiconductor wafer, forming a polymer layer on at least a portion of the sensor surface and around portions of the conductive terminals along the side of the semiconductor die, forming solder on ends of the respective conductive terminals, separating a semiconductor die from the semiconductor wafer, the semiconductor die having the sensor surface of the side and the conductive terminals, attaching the semiconductor die to a substrate with the solder between the ends of the respective conductive terminals and respective conductive features of the substrate, performing a thermal process that reflows the solder to solder the ends of the respective conductive terminals to the respective conductive features of the substrate, and performing a molding process that forms a molded package structure that encloses a portion of the semiconductor die and extends to a portion of the substrate, the molded package structure having a cavity that extends along the third direction between the sensor surface and the substrate, the cavity extending in the first and second directions in an interior of the cage structure formed by the conductive terminals.

In another aspect a method includes forming first conductive terminals along a side of a semiconductor wafer in a cage structure that laterally surrounds a sensor surface of the side of the semiconductor wafer, and concurrently forming second conductive terminals extending outward from the side and interleaved between respective pairs of the first conductive terminals in the cage structure, with the second conductive terminals disconnected from circuitry of the semiconductor die. The method also includes forming solder on ends of the respective first conductive terminals, separating a semiconductor die from the semiconductor wafer, attaching the semiconductor die to a substrate with the ends of the respective first conductive terminals soldered to the respective conductive features of the substrate, and performing a molding process that forms a molded package structure that encloses a portion of the semiconductor die and extends to a portion of the substrate, the molded package structure having a cavity that extends between the sensor surface and the substrate in an interior of the cage structure.

### BRIEF DESCRIPTION OF THE DRAWINGS

FIG. 1 is a sectional side elevation view of an electronic device having a molded package structure with a cavity under a sensor surface of a semiconductor die.

FIG. 1A is a partial sectional bottom view of the electronic device taken along line 1A-1A of FIG. 1.

FIG. 2 is a flow diagram of a method of fabricating an electronic device.

FIGS. 3-11 are partial sectional side elevation and bottom views of the electronic device of FIGS. 1 and 1A undergoing fabrication processing according to the method of FIG. 2.

FIG. 12 is a sectional side elevation view of another electronic device having a molded package structure with a cavity under a sensor surface of a semiconductor die.

FIG. 12A is a partial sectional bottom view of the electronic device taken along line 12A-12A of FIG. 12.

FIGS. 13-15 are partial sectional side elevation views of the electronic device of FIGS. 12 and 12A undergoing fabrication processing according to the method of FIG. 2.

FIG. 16 is a sectional side elevation view of another electronic device having a molded package structure with a cavity under a sensor surface of a semiconductor die.

FIG. 16A is a partial sectional bottom view of the electronic device taken along line 16A-16A of FIG. 16.

FIGS. 17 and 18 are partial sectional side elevation views of the electronic device of FIGS. 16 and 16A undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating.

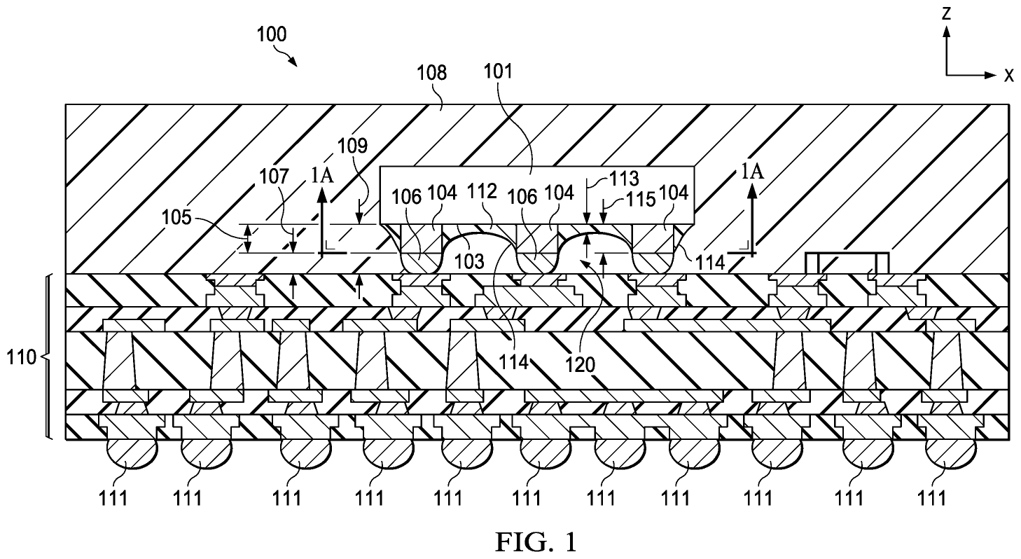

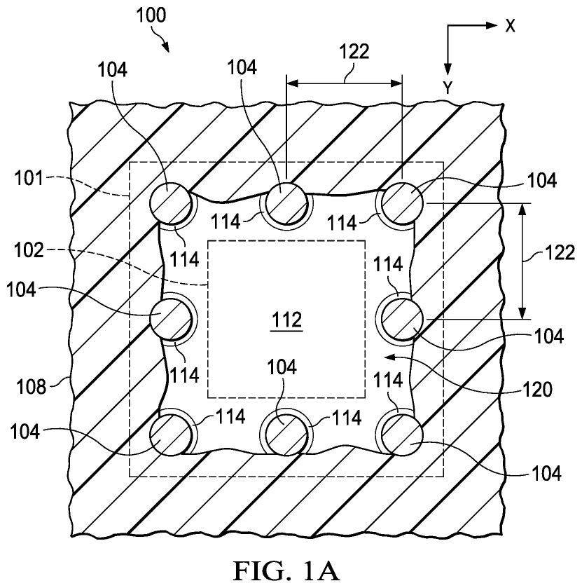

FIGS. 1 and 1A show an electronic device 100 having a semiconductor die 101. The electronic device 100 is illustrated in an example position in a three-dimensional space with respective first, second, and third mutually orthogonal directions X, Y, and Z. The semiconductor die 101 has a sensor surface 102 extending along a bottom side 103 of the semiconductor die 101 in an X-Y plane of the first and second directions X and Y. The electronic device 100 includes conductive terminals 104, for example, copper pillars. The conductive terminals 104 extend outward from the side 103 of the semiconductor die 101 along the third direction Z (e.g., downward in the orientation shown in FIG. 1) by a non-zero terminal height 105. In one example, the terminal height 105 is 35 μm or less. In this or another example, the conductive terminals 104 have a diameter in the first and second directions X, Y of 60 μm or more and 70 μm or less. As best shown in FIG. 1A, the conductive terminals 104 are spaced apart from one another and from the sensor surface 102 in the first and second directions X and Y, and the conductive terminals 104 form a cage structure that laterally surrounds the sensor surface 102. As shown in FIG. 1, moreover, the respective conductive terminals 104 have solder 106 at the lower ends thereof. The solder structures 106 have a height or thickness 107 along the third direction Z.

The electronic device 100 includes a molded package structure 108 and a substrate 110, such as a multilevel package substrate with conductive (e.g., copper or aluminum) traces and vias in and between stacked layers of dielectric laminate materials, and solder balls 111 for soldering the electronic device 100 to a host printed circuit board (PCB, not shown). The package structure 108 is molded using molding compound. Molding compounds, such as epoxy mold compounds are encapsulation materials made of a resin, for example, a polymer resin material with filler particles. In one example, epoxy mold compound includes an epoxy resin-matrix with the addition of filler particles such as silica or alumina filler particles, and the filler particles are characterized by their average size and shape. Example filler particles include silicon dioxide (SiO₂), aluminum oxide (e.g., Al₂O₃), ceramic particles, etc. The semiconductor die 101 is flip chip mounted or attached to the substrate 110. The lower ends of the conductive terminals 104 are soldered to conductive features of the substrate 110 such that the side 103 of the semiconductor die 101 is spaced apart from the substrate 110 along the third direction Z by a non-zero spacing distance 109 that is less than an average filler particle size of the material of the molded package structure 108. In one example, the non-zero spacing distance 109 is 45 μm or less. In this or another example, the non-zero spacing distance 109 is 30 μm or more and 35 μm or less.

The molded package structure 108 encloses a portion of the semiconductor die 101 and extends to a portion of the substrate 110. The electronic device 100 in one example includes a polymer layer 112 having a nominal thickness 113. The polymer layer 112 in one example has thicker raised portions 114 with a larger thickness 115 along the third direction Z. In one example, the thickness 115 is approximately equal to the terminal height 105. In this or another example, the thickness 115 is less than or equal to the terminal height 105. The polymer layer 112, 114 in one example is or includes polyimide and extends on at least a portion of the sensor surface 102. The raised or thicker portions 114 of the polymer layer 112 in the illustrated example extends around portions of the conductive terminals 104 along the side 103 of the semiconductor die 101.

The molded package structure 108 has a cavity 120 that extends along the third direction Z between the sensor surface 102 and the substrate 102. The cavity 120 extends in the first and second directions X and Y in an interior of the cage structure formed by the conductive terminals 104. The conductive terminals 104 are spaced apart from one another by a pitch distance 122 in the first and second directions. The diameters of the conductive terminals 104, the pitch distance 122, and the Z direction spacing 109 of the lower side 103 of the semiconductor die 101 from the upper side of the substrate 110 create an impediment to molding material entering the area of the cavity 120. In manufacturing and in device operation, the cavity mitigates stress on the sensor surface 102 of the semiconductor die 101. The cage structure of the conductive terminals 104 alone or in combination with the polymer layer 112 mitigates or prevents molding compound material from entering the interior of the cage structure during molding and the resulting cavity 120 helps mitigate mechanical stress at the sensor surface 102 along a bottom side 103 of the semiconductor die 101.

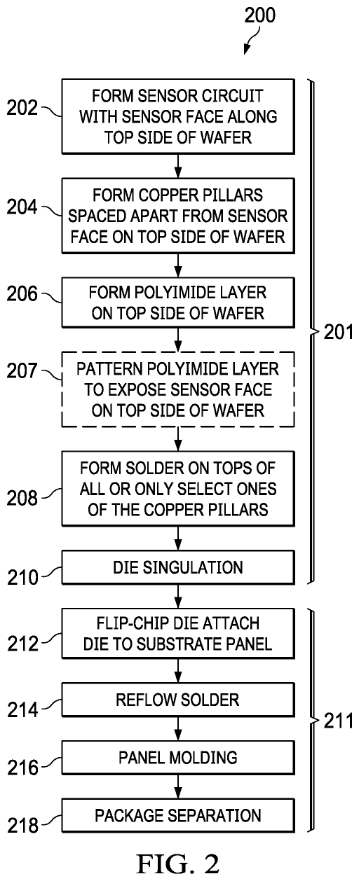

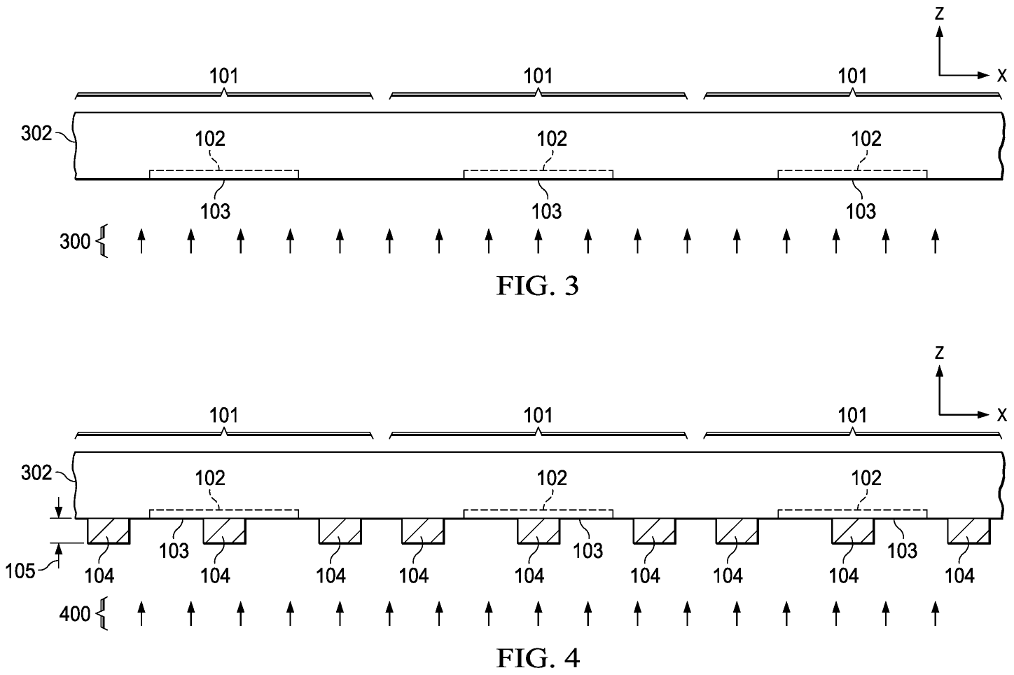

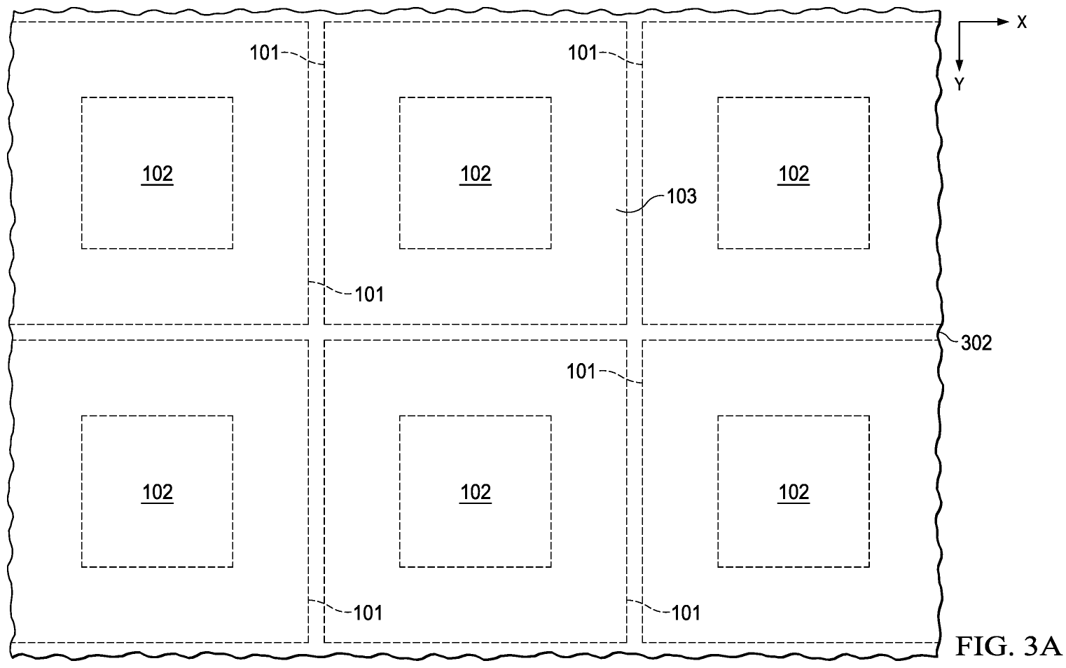

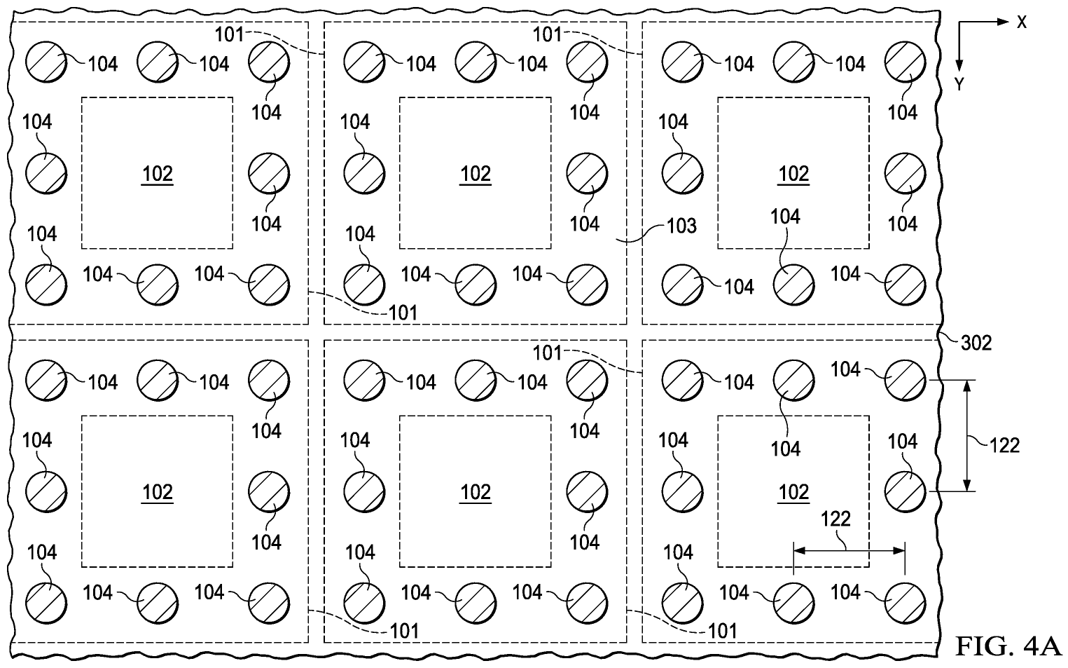

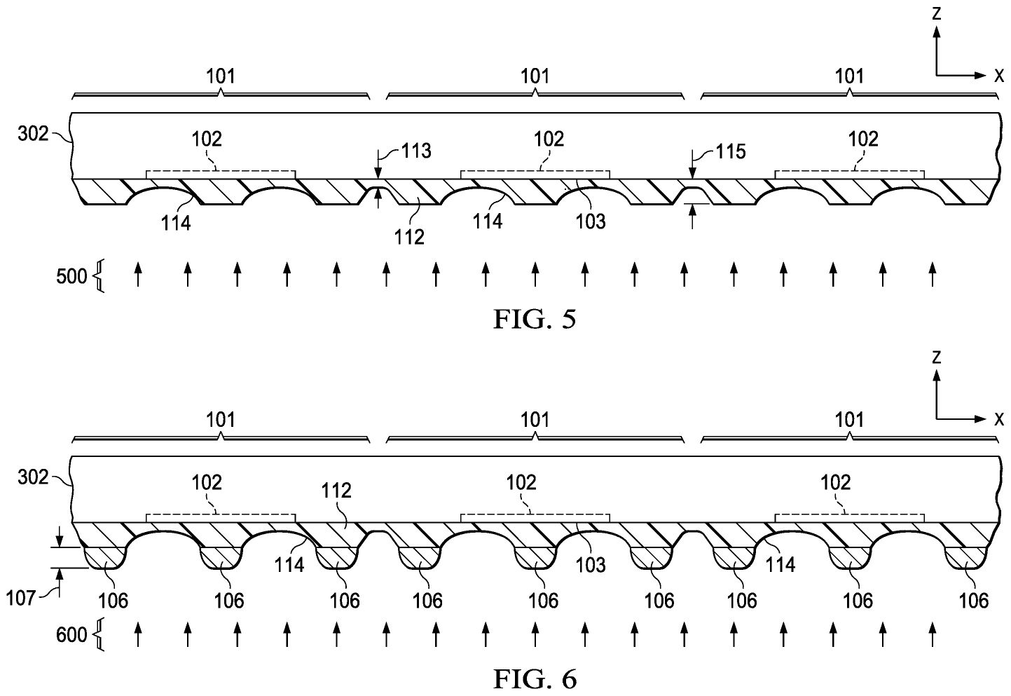

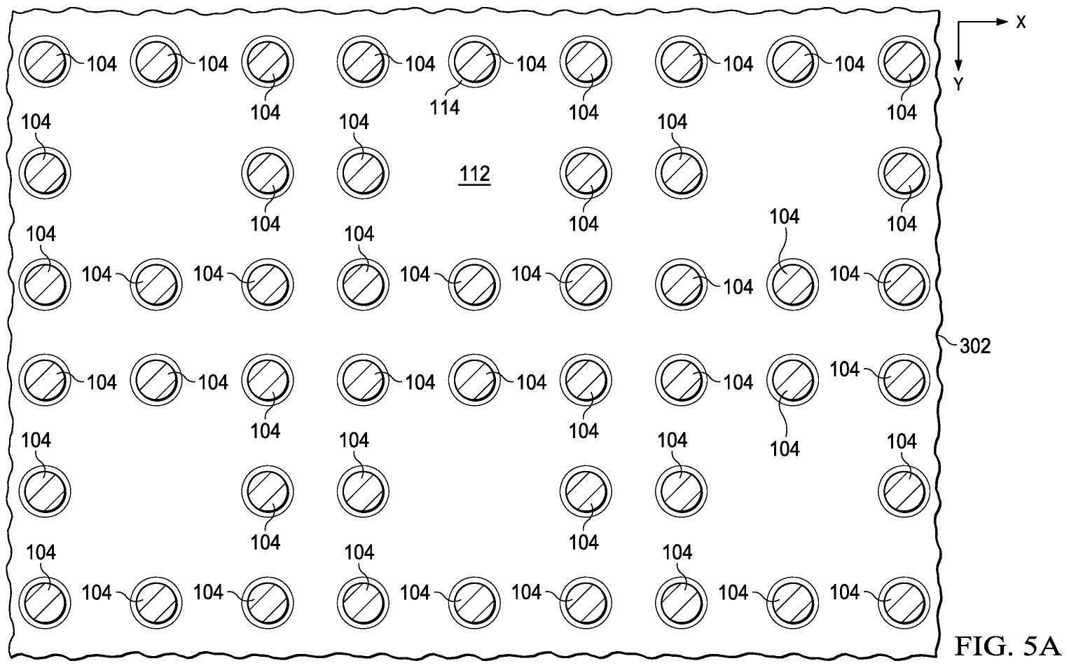

Referring also to FIGS. 2-11, FIG. 2 shows a method 200 of fabricating an electronic device and FIGS. 3-11 show the electronic device 100 undergoing fabrication processing according to the method 200. The method 200 includes semiconductor wafer processing at 201 with formation of a sensor circuit at 202 with a sensor surface (e.g., sensor face) along the top side of the wafer. FIGS. 3 and 3A show one example, in which wafer fabrication process 300 is performed on a semiconductor wafer 302 to form the sensor surface 102 along the side 103 of multiple prospective die areas 101 of the processed wafer 302. The method 200 continues at 204 with formation of the conductive terminals 104. FIGS. 4 and 4A show one example, in which a copper pillar formation process 400 is performed that forms the conductive terminals 104 along the side 103 of the semiconductor wafer 302. The wafer side 103 extends in an X-Y plane of the respective first and second directions X and Y, and the conductive terminals 104 extend outward from the side 103 along the third direction Z by the terminal height 105, such as 35 μm or less in one example. As shown in FIG. 4A, the conductive terminals 104 of each prospective die area 101 of the wafer 302 are spaced apart from one another by the pitch distance 122 and form a cage structure that laterally surrounds the respective sensor surface 102 of the side 103 of the semiconductor wafer 302 in the first and second directions X and Y. The method 200 continues at 206 with forming the polymer layer. FIGS. 5 and 5A show one example, in which a deposition process 500 is performed that forms the polymer layer 112, 114 (e.g., polyimide) on all or a portion of the sensor surface 102 and around portions of the conductive terminals 104 along the side 103 of the semiconductor wafer 302. In one example, the method 200 further includes patterning the polymer layer 112, 114 at 207 in FIG. 2. In another example, the patterning at 207 is omitted.

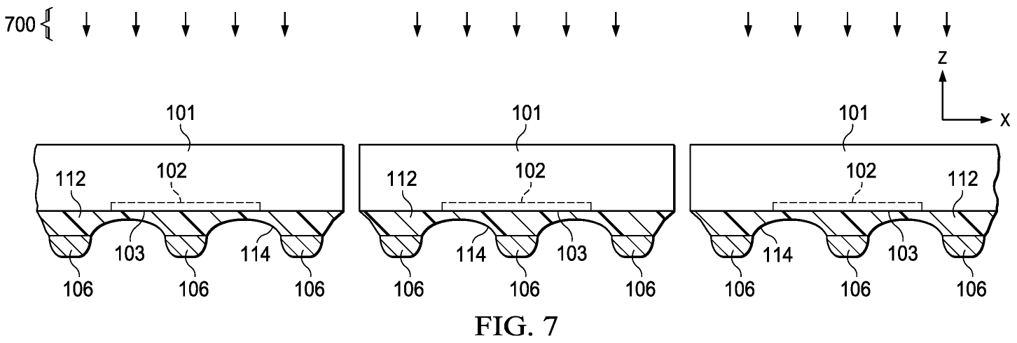

The wafer processing 201 of the method 200 continues at 208 in FIG. 2 with forming solder on the tops (e.g., ends) of the conductive terminals 104 at 208. FIG. 6 shows one example, in which a solder dipping process 600 is performed that forms the solder 106 on ends of the respective conductive terminals 104 to a thickness 107. At 210 in FIG. 2, the wafer processing 201 includes die singulation at 210. FIG. 7 shows one example, in which a die singulation or separation process 700 is performed (e.g., saw or laser cutting) that separates individual semiconductor dies 101 from the wafer 302.

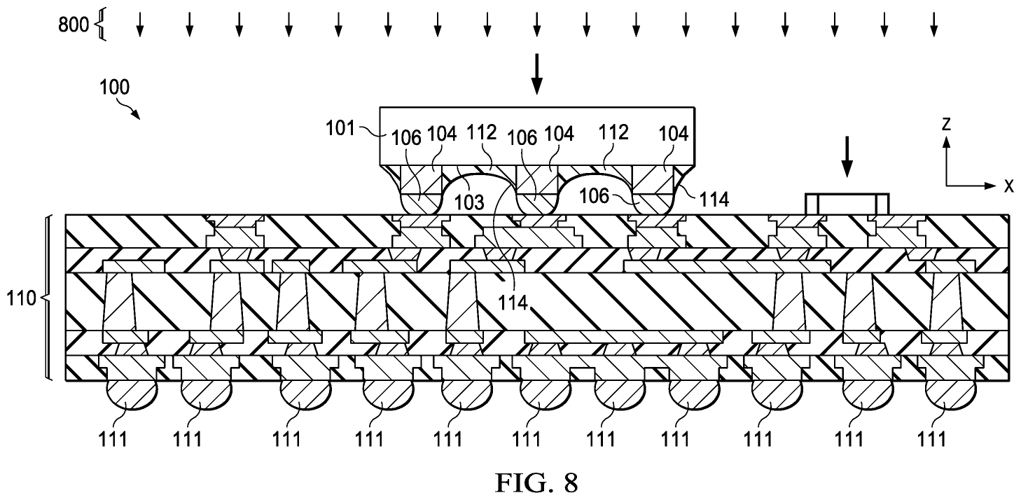

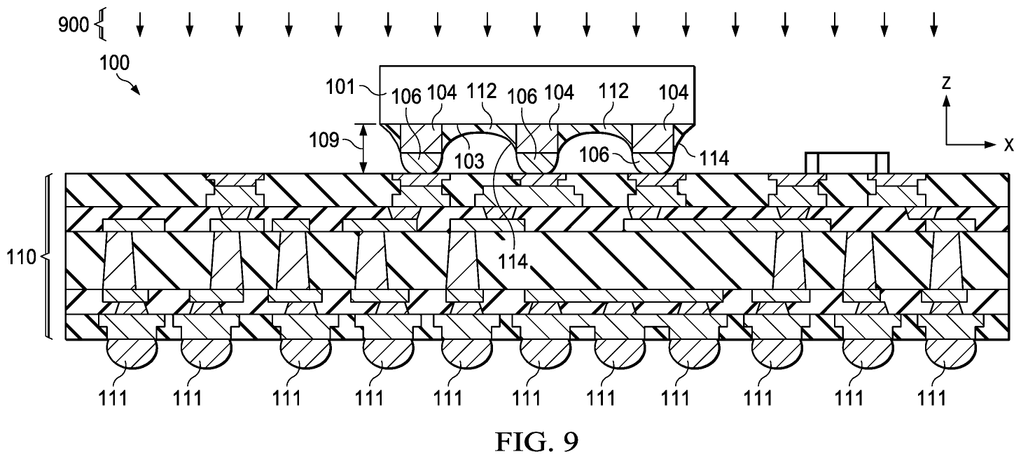

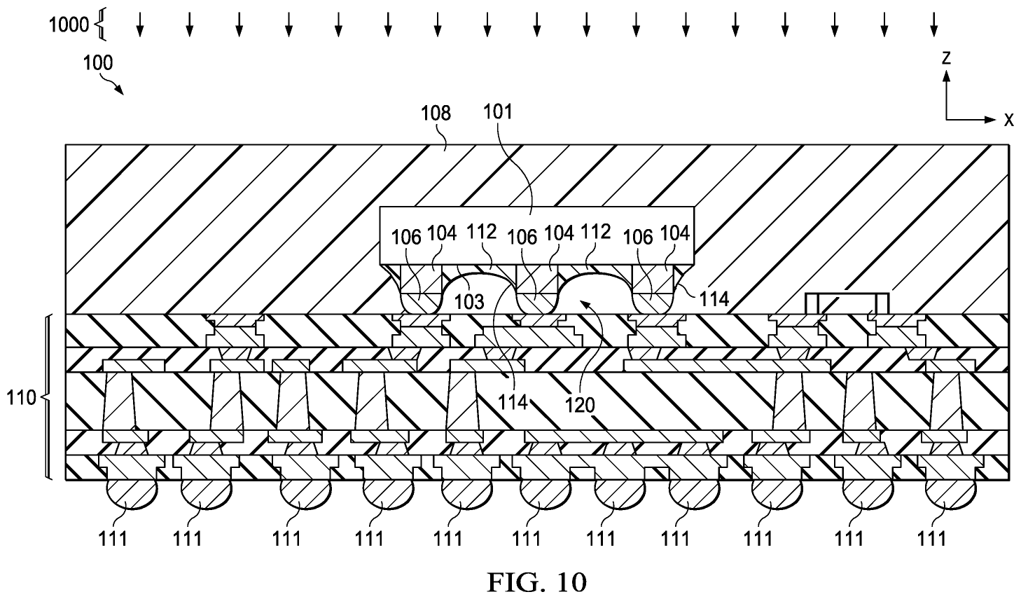

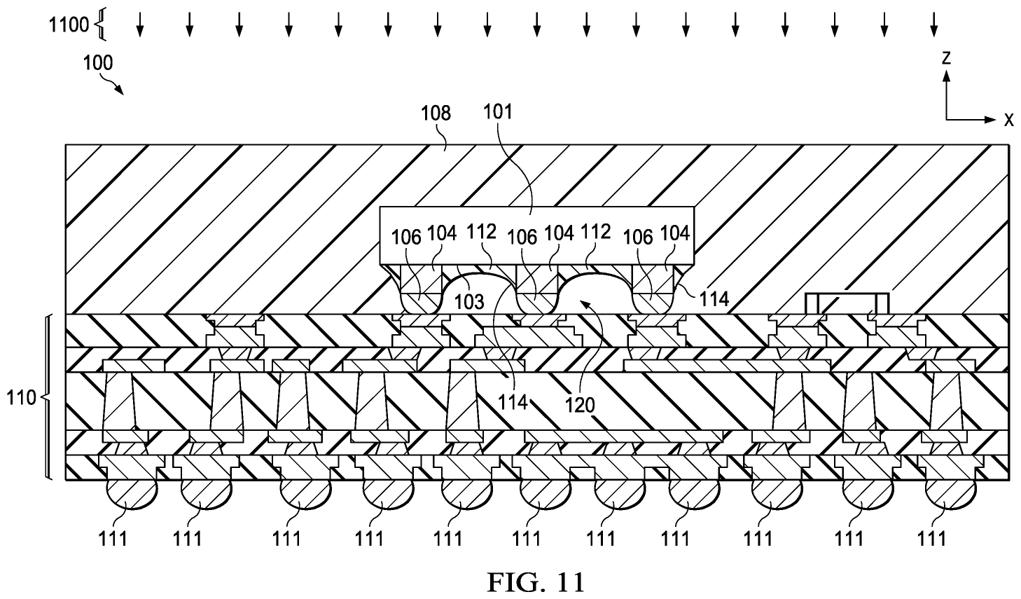

The method 200 in FIG. 2 continues with packaging processing at 211, including flip-chip die attachment at 212. FIG. 8 shows one example, in which an automated pick and place process 800 is performed that positions the singulated semiconductor die 101 on a top side of the multilayer package substrate 119, with the solder 106 at the ends of the respective conductive terminals 104 engaging corresponding conductive features (e.g., copper landing areas or pads) of the substrate 110. The pick and place process 800 in one example also places other components (e.g., surface mount technology or SMT capacitors, resistors, other dies, etc.) on corresponding conductive features of the top side of the substrate 110 as shown in FIG. 8. The packaging processing 211 in this example also includes reflowing the solder at 214. FIG. 9 shows one example, in which a thermal reflow process 900 is performed that reflows the solder 106 and sets the final standoff or non-zero spacing distance 109 of 45 μm or less (e.g., 30 μm or more and 35 μm or less). The method 200 also includes molding at 216. FIG. 10 shows one example, in which a molding process 1000 is performed that forms the molded package structure 108 that encloses a portion of the semiconductor die 101 and extends to a portion of the substrate 110. As shown in FIGS. 1, 1A and 10, the molded package structure 108 has the cavity 120 that extends along the third direction Z between the sensor surface 102 and the substrate 102, and the cavity 120 extends in the first and second directions X, Y in an interior of the cage structure formed by the conductive terminals 104. The packaging is completed with package separation at 218 in FIG. 2, for example, in cases where the die attach and other packaging processing steps are performed in a panel or strip with a panel substrate 110 and rows and columns of prospected final device areas that are processed concurrently and/or sequentially. FIG. 11 shows one example of final device package separation, in which a cutting or other separation process 1100 is performed that separates the final packaged electronic device 100 from a panel structure.

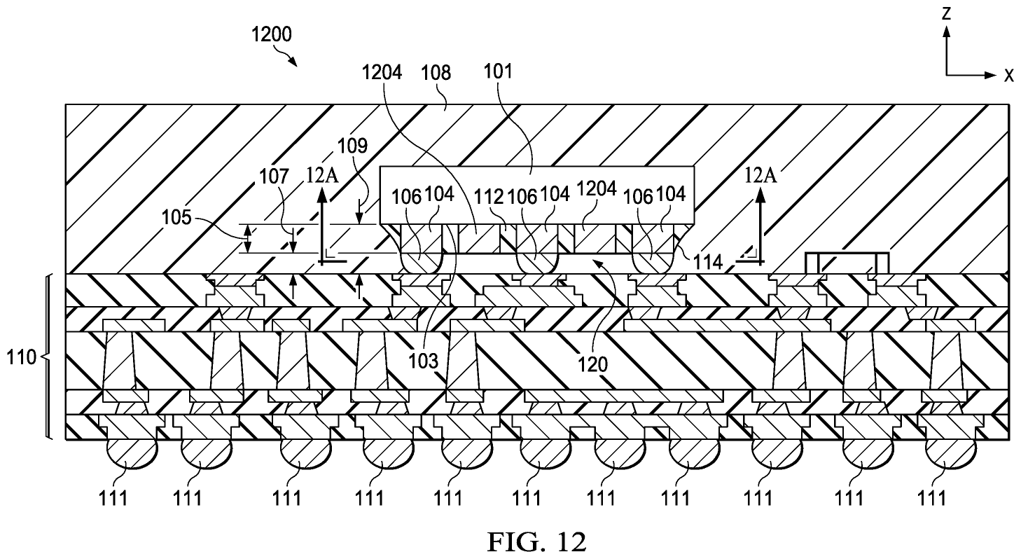

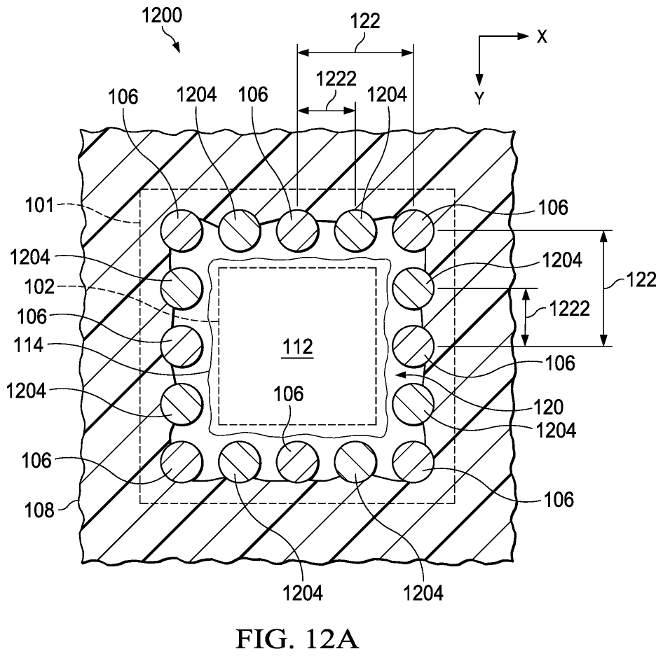

Referring now to FIGS. 12-15, FIGS. 12 and 12A show another example electronic device 1200 having a molded package structure 108 and other similarly numbered features and structures as described above, including a cavity 120 in the molded package structure that extends under the sensor surface 102 of the semiconductor die 101. In this example, the semiconductor die 101 includes the above described first conductive terminals 104 (e.g., copper pillars). In addition, the semiconductor die 101 includes second conductive terminals 1204 extending outward from the side 103 of the die 101 along the third direction Z toward the substrate 110. The individual second conductive terminals 1204 are interleaved between a respective pair of the conductive terminals 104 in the cage structure. The second conductive terminals 1204 are spaced apart from the substrate 110, and the second conductive terminals 1204 are disconnected from circuitry of the semiconductor die 101. In this example, moreover, the second conductive terminals 1204 do not have any solder 106. As in the example of FIG. 1 above, the first conductive terminals 104 are spaced apart from one another by the pitch distance 122. The second conductive terminals 1204 in this example are spaced apart from and approximately midway between the respective pair of first conductive terminals 104 to provide a lateral spacing pitch 1222 that is approximately half the pitch spacing 122 of the first conductive terminals 104. In one example, the lateral spacing between adjacent pairs of the first conductive terminals 104 and the second conductive terminals 1204 is less than the average filler particle size of the material of the molded package structure 108. In one example, the lateral spacing is 45 μm or less, such as 30 to 35 μm. This example also includes the polymer layer 112, 114 as described above. In another implementation, the polymer layer 112, 114 is omitted. In these or another implementation, the first conductive terminals 104 and the second conductive terminals 1204 have approximately equal terminal heights 105. In another example, the first and second conductive terminals 104 and 1204 have different heights. The close lateral spacing of the conductive terminals 104 and 1204 forms a cage structure that mitigates ingression of molding material during molding to facilitate formation of the cavity 120 in the molded package structure 108.

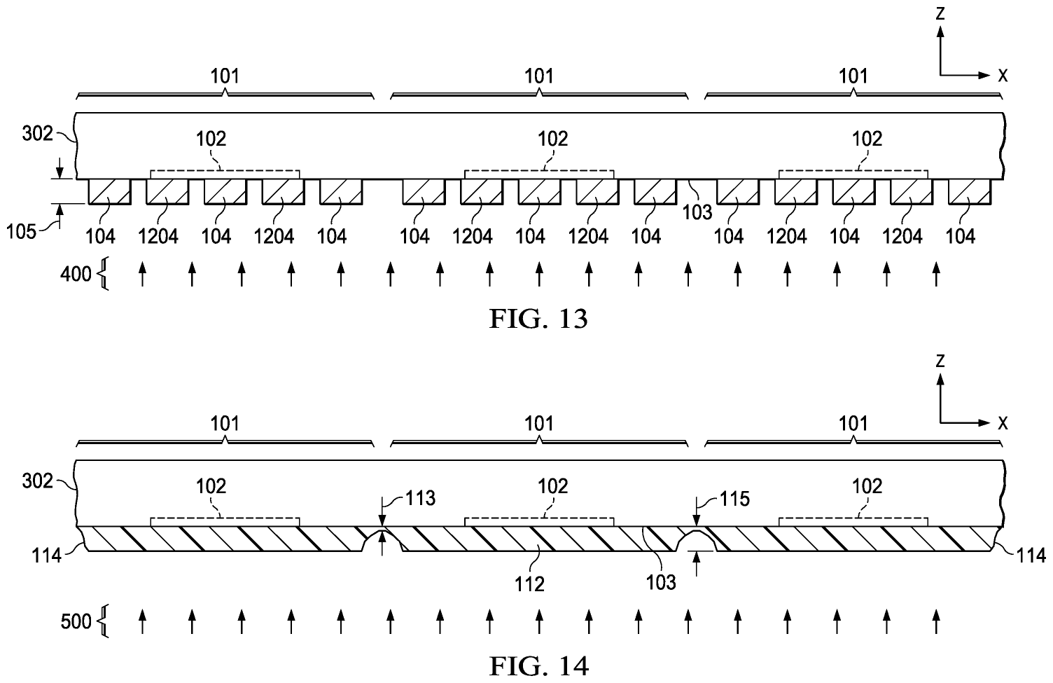

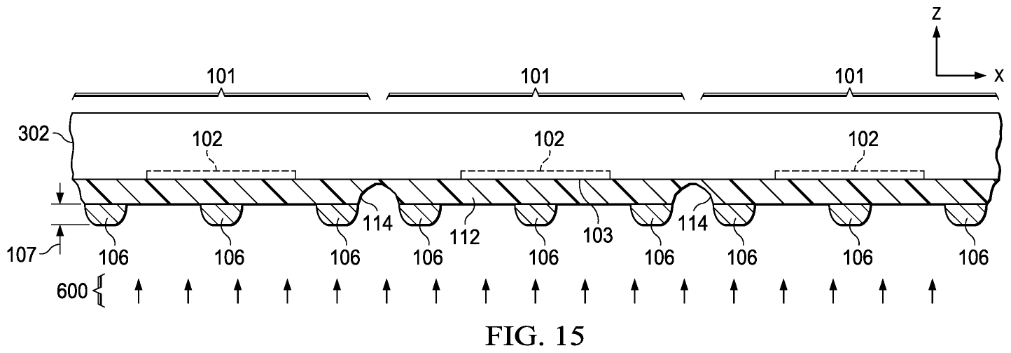

FIGS. 13-15 show examples of the electronic device 1200 undergoing fabrication according to the method 200 in FIG. 2 above. FIG. 13 shows one example of conductive terminal formation (e.g., at 204 in FIG. 2), in which the pillar formation process 400 concurrently forms the first conductive terminals 104 and the second conductive terminals 1204 to approximately equal heights 105. FIG. 14 shows one example of subsequent formation of the polymer layer 112, 114 using a deposition process 500 (e.g., at 206 in FIG. 2), and FIG. 15 shows one example of the solder formation at 208. In one example, the solder formation process 600 uses a stencil (not shown) for selective application of the solder 106 by dipping, where the stencil has openings corresponding to the first conductive terminals 104 but no openings that correspond to the second conductive terminals 1204. Accordingly, the process 600 forms the solder structures 106 on the ends of the first conductive terminals 104 but no solder is formed on the second conductive terminals 1204 as shown in FIG. 15. This advantageously mitigates solder bridging during flip chip die attach processing (e.g., 212 and 1214 in FIG. 2) and the disconnection of the second conductive terminals 1204 from circuitry of the semiconductor die 101 maintains the design circuit spacing provided by the pith spacing of the first conductive leads 104 (FIG. 12A).

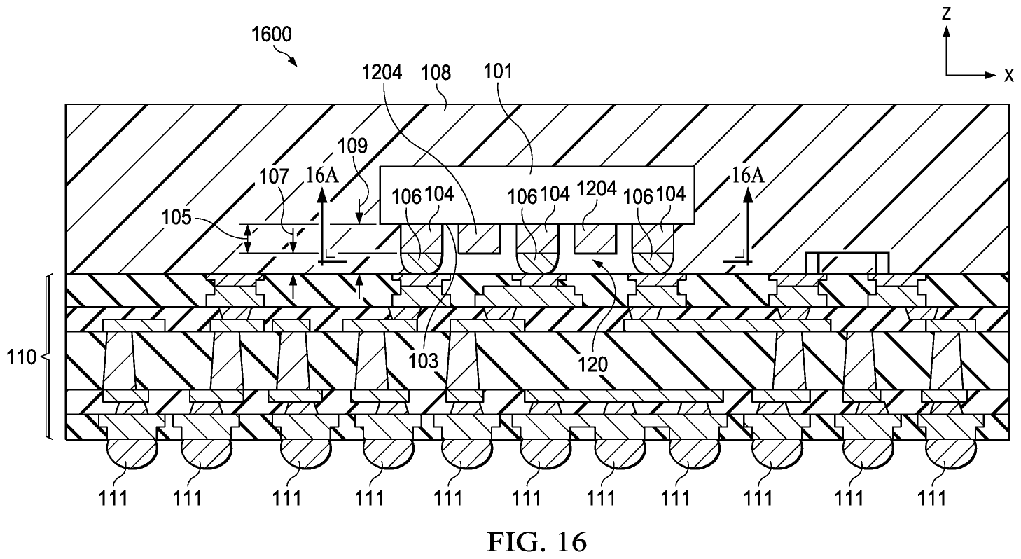

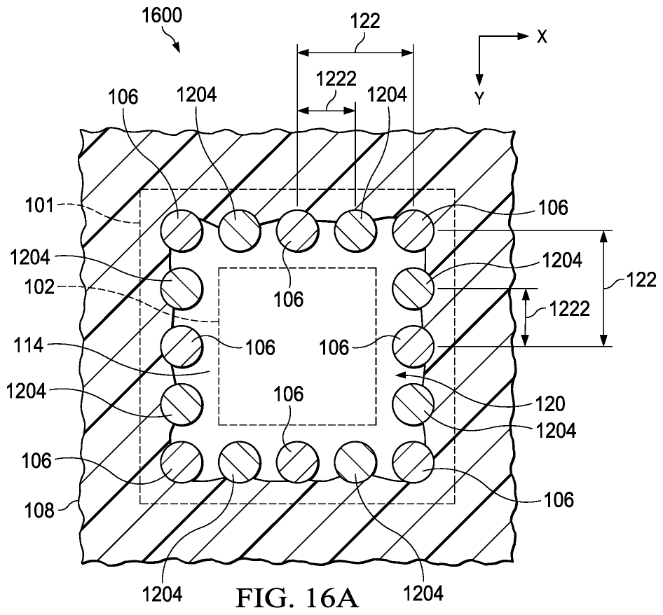

Referring also to FIGS. 16-18, FIGS. 16 and 16A show another example electronic device 1600 having a molded package structure 108 and other similarly numbered features and structures as described above, including a cavity 120 in the molded package structure that extends under the sensor surface 102 of the semiconductor die 101. The semiconductor die 101 in this example includes the first conductive terminals 104 (e.g., copper pillars). In addition, the semiconductor die 101 includes second conductive terminals 1204 extending outward from the side 103 of the die 101 along the third direction Z toward the substrate 110. The individual second conductive terminals 1204 are interleaved between a respective pair of the conductive terminals 104 in the cage structure. The second conductive terminals 1204 are spaced apart from the substrate 110, and the second conductive terminals 1204 are disconnected from circuitry of the semiconductor die 101. In this example, moreover, the second conductive terminals 1204 do not have any solder 106. As in the example of FIGS. 1 and 12, the first conductive terminals 104 are spaced apart from one another by the pitch distance 122. The second conductive terminals 1204 in this example are spaced apart from and approximately midway between the respective pair of first conductive terminals 104 to provide a lateral spacing pitch 1222 that is approximately half the pitch spacing 122 of the first conductive terminals 104. Unlike the example of FIG. 12, however, the electronic device 1600 does not have a polymer layer and the sensing surface 102 of the semiconductor die 101 is exposed to the cavity 120 of the mold in the interior of the cage structure formed by the first conductive terminals 104 and the second conductive terminals 1204. In this example, the close lateral spacing of the conductive terminals 104 and 1204 forms a cage structure that mitigates ingression of molding material during molding to facilitate formation of the cavity 120 in the molded package structure 108.

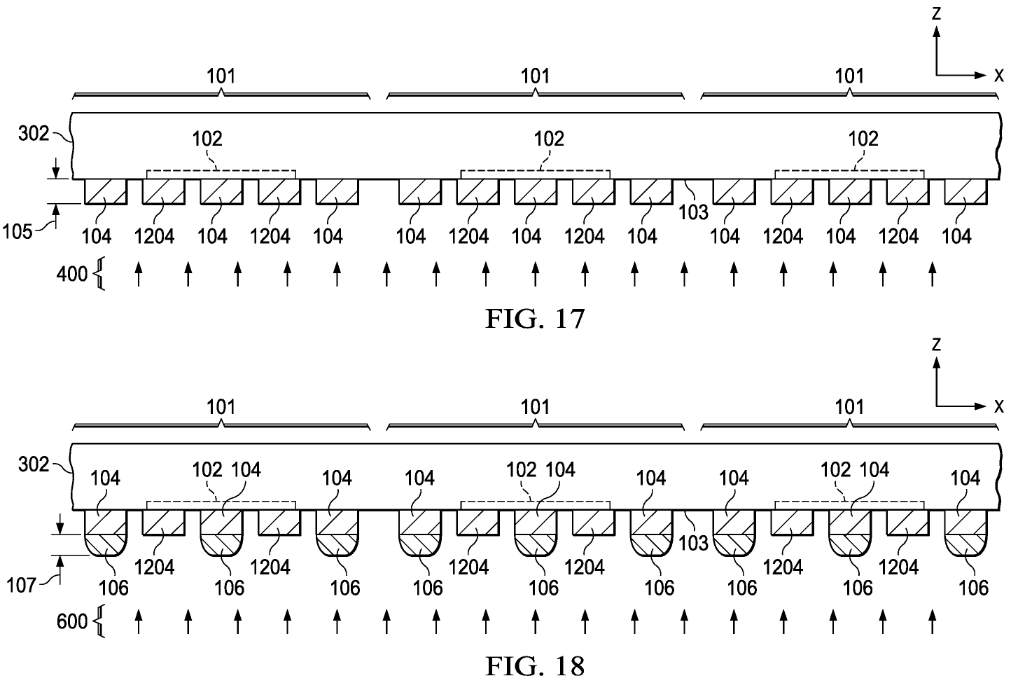

FIGS. 17 and 18 show examples of the electronic device 1600 undergoing fabrication according to the method 200 in FIG. 2 above. FIG. 17 shows one example of conductive terminal formation (e.g., at 204 in FIG. 2), in which the pillar formation process 400 concurrently forms the first conductive terminals 104 and the second conductive terminals 1204 to approximately equal heights 105. FIG. 18 shows one example of the solder formation at 208 of FIG. 2. In the example of the solder formation process 600 in FIG. 18, a stencil (not shown) is used for selective application of the solder 106 by dipping, where the stencil has openings corresponding to the first conductive terminals 104 but no openings that correspond to the second conductive terminals 1204. Accordingly, the process 600 forms the solder structures 106 on the ends of the first conductive terminals 104 but no solder is formed on the second conductive terminals 1204 as shown in FIG. 15. This advantageously mitigates solder bridging during flip chip die attach processing (e.g., 212 and 214 in FIG. 2) and the disconnection of the second conductive terminals 1204 from circuitry of the semiconductor die 101 maintains the design circuit spacing provided by the pith spacing of the first conductive leads 104 (FIG. 16A).

The above examples are merely illustrative of several possible implementations of various aspects of the present disclosure, wherein equivalent alterations and/or modifications will occur to others skilled in the art upon reading and understanding this specification and the annexed drawings. Unless otherwise stated, “about,” “approximately,” or “substantially” preceding a value means+/−10 percent of the stated value. Modifications are possible in the described examples, and other implementations are possible, within the scope of the claims.

What is claimed is:

1. An electronic device, comprising:
a substrate;
a semiconductor die having a side that extends in a plane of orthogonal first and second directions, a sensor surface extending along the side, and conductive terminals extending outward from the side along a third direction that is orthogonal to the first and second directions, the conductive terminals spaced apart from one another and from the sensor surface in the first and second directions, the respective conductive terminals having ends soldered to conductive features of the substrate such that the side of the semiconductor die is spaced apart from the substrate along the third direction, and the conductive terminals forming a cage structure that laterally surrounds the sensor surface; and
a molded package structure that encloses a portion of the semiconductor die and extends to a portion of the substrate, the molded package structure having a cavity that extends along the third direction between the sensor surface and the substrate, the cavity extending in the first and second directions in an interior of the cage structure formed by the conductive terminals.

2. The electronic device of claim 1, further comprising a polymer layer on at least a portion of the sensor surface in the cavity of the molded package structure.

3. The electronic device of claim 2, wherein the polymer layer includes polyimide.

4. The electronic device of claim 2, wherein the polymer layer extends around portions of the conductive terminals along the side of the semiconductor die.

5. The electronic device of claim 2, wherein the side of the semiconductor die is spaced apart from the substrate along the third direction by a non-zero spacing distance that is less than an average filler particle size of the material of the molded package structure.

6. The electronic device of claim 5, wherein the non-zero spacing distance is 45 μm or less.

7. The electronic device of claim 5, wherein the conductive terminals have a diameter in the first and second directions of 60 μm or more and 70 μm or less.

8. The electronic device of claim 5, wherein the semiconductor die further includes second conductive terminals extending outward from the side along the third direction toward the substrate, the individual second conductive terminals interleaved between a respective pair of the conductive terminals in the cage structure, the second conductive terminals spaced apart from the substrate, and the second conductive terminals disconnected from circuitry of the semiconductor die.

9. The electronic device of claim 2, wherein the semiconductor die further includes second conductive terminals extending outward from the side along the third direction toward the substrate, the individual second conductive terminals interleaved between a respective pair of the conductive terminals in the cage structure, the second conductive terminals spaced apart from the substrate, and the second conductive terminals disconnected from circuitry of the semiconductor die.

10. The electronic device of claim 1, wherein the side of the semiconductor die is spaced apart from the substrate along the third direction by a non-zero spacing distance that is less than an average filler particle size of the material of the molded package structure.

11. The electronic device of claim 10, wherein the non-zero spacing distance is 45 μm or less.

12. The electronic device of claim 10, wherein the conductive terminals have a diameter in the first and second directions of 60 μm or more and 70 μm or less.

13. The electronic device of claim 10, wherein the semiconductor die further includes second conductive terminals extending outward from the side along the third direction toward the substrate, the individual second conductive terminals interleaved between a respective pair of the conductive terminals in the cage structure, the second conductive terminals spaced apart from the substrate, and the second conductive terminals disconnected from circuitry of the semiconductor die.

14. The electronic device of claim 1, wherein the semiconductor die further includes second conductive terminals extending outward from the side along the third direction toward the substrate, the individual second conductive terminals interleaved between a respective pair of the conductive terminals in the cage structure, the second conductive terminals spaced apart from the substrate, and the second conductive terminals disconnected from circuitry of the semiconductor die.

15. A method, comprising:
forming conductive terminals along a side of a semiconductor wafer, the side extending in a plane of orthogonal first and second directions, the conductive terminals extending outward from the side along a third direction that is orthogonal to the first and second directions by a terminal height that is 35 μm or less, the conductive terminals spaced apart from one another and forming a cage structure that laterally surrounds a sensor surface of the side of the semiconductor wafer in the first and second directions;
forming a polymer layer on at least a portion of the sensor surface and around portions of the conductive terminals along the side of the semiconductor wafer;
forming solder on ends of the respective conductive terminals;
separating a semiconductor die from the semiconductor wafer, the semiconductor die having the sensor surface of the side and the conductive terminals;
attaching the semiconductor die to a substrate with the solder between the ends of the respective conductive terminals and respective conductive features of the substrate;
performing a thermal process that reflows the solder to solder the ends of the respective conductive terminals to the respective conductive features of the substrate; and
performing a molding process that forms a molded package structure that encloses a portion of the semiconductor die and extends to a portion of the substrate, the molded package structure having a cavity that extends along the third direction between the sensor surface and the substrate, the cavity extending in the first and second directions in an interior of the cage structure formed by the conductive terminals.

16. The method of claim 15, wherein the terminal height and a thickness of the solder along the third direction are such that after the thermal process that reflows the solder, the side of the semiconductor die is spaced apart from the substrate along the third direction by a non-zero spacing distance that is less than an average filler particle size of the material of the molded package structure.

17. The method of claim 15, wherein:
the conductive terminals include copper and have a diameter in the first and second directions of 60 μm or more and 70 μm or less; and
the polymer layer includes polyimide.

18. The method of claim 15, further comprising:
concurrently with forming the conductive terminals, forming second conductive terminals extending outward from the side along the third direction, the individual second conductive terminals interleaved between a respective pair of the conductive terminals in the cage structure, and the second conductive terminals disconnected from circuitry of the semiconductor die.

19. A method, comprising:
forming first conductive terminals along a side of a semiconductor wafer, the side extending in a plane of orthogonal first and second directions, the first conductive terminals extending outward from the side along a third direction that is orthogonal to the first and second directions, the first conductive terminals spaced apart from one another and forming a cage structure that laterally surrounds a sensor surface of the side of the semiconductor wafer in the first and second directions;
concurrently with forming the first conductive terminals, forming second conductive terminals extending outward from the side along the third direction, the individual second conductive terminals interleaved between a respective pair of the first conductive terminals in the cage structure, and the second conductive terminals disconnected from circuitry of the semiconductor wafer;
forming solder on ends of the respective first conductive terminals;
separating a semiconductor die from the semiconductor wafer, the semiconductor die having the sensor surface of the side and the first and second conductive terminals;
attaching the semiconductor die to a substrate with the solder between the ends of the respective first conductive terminals and respective conductive features of the substrate;
performing a thermal process that reflows the solder to solder the ends of the respective first conductive terminals to the respective conductive features of the substrate; and
performing a molding process that forms a molded package structure that encloses a portion of the semiconductor die and extends to a portion of the substrate, the molded package structure having a cavity that extends along the third direction between the sensor surface and the substrate, the cavity extending in the first and second directions in an interior of the cage structure formed by the first conductive terminals.

20. The method of claim 19, further comprising:
before forming solder on ends of the respective first conductive terminals, forming a polymer layer on at least a portion of the sensor surface and around portions of the first and second conductive terminals along the side of the semiconductor die.
